(19) United States
(12) Patent Application Publication
(10) Pub. No.: US 2024/0339797 A1
(43) Pub. Date: Oct. 10, 2024

(54) GAS LASER DEVICE AND ELECTRONIC DEVICE MANUFACTURING METHOD

(71) Applicant: Gigaphoton Inc., Tochigi (JP)

(72) Inventors: Yoichi SASAKI, Oyama-shi (JP); Hiroshi UMEDA, Oyama-shi (JP); Jeffrey P. SERCEL, Manchester, NH (US); Michael von DADELSZEN, Manchester, NH (US)

(73) Assignee: Gigaphoton Inc., Tochigi (JP)

(21) Appl. No.: 18/746,278

(22) Filed: Jun. 18, 2024

Related U.S. Application Data
(63) Continuation of application No. PCT/JP2022/040572, filed on Oct. 30, 2022.
(60) Provisional application No. 63/266,089, filed on Dec. 28, 2021.

(51) Int. Cl. H01S 3/038; G03F 7/00

(52) U.S. Cl. CPC H01S 3/038; G03F 7/70025

(57) ABSTRACT

A gas laser device includes a laser chamber including an opening, an electrical insulating portion blocking the opening, a first electrode, and a second electrode facing the first electrode. The first electrode includes a contact region contacting the surface of the electrical insulating portion, an opposing surface facing the second electrode, and a first curved surface included in a region between the contact region and the opposing surface and convexly curved toward an outer side of the first electrode. In a cross section of the first electrode along a surface extending in a separation direction of the first electrode and the second electrode, the contact region is located on an inner side of the first electrode with respect to the first curved surface, and the first curved surface is a part of a circumference of a circle or an ellipse which does not intersect the electrical insulating portion.

### CROSS-REFERENCE TO RELATED APPLICATIONS

The present application claims the benefit of International Application No. PCT/JP2022/040572, filed on Oct. 30, 2022, the entire contents of which are hereby incorporated by reference.

### BACKGROUND

### 1. Technical Field

The present disclosure relates to a gas laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 pm to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: U.S. Pat. No. 9,246,298
Patent Document 2: International Publication No. WO2005/013440

### SUMMARY

A gas laser device according to an aspect of the present disclosure includes a conductive laser chamber including an opening and a pair of windows, an electrical insulating portion blocking the opening, a first electrode fixed to a surface of the electrical insulating portion on a side of an internal space of the laser chamber, and a second electrode facing the first electrode at the internal space of the laser chamber. Here, a laser gas is enclosed at the internal space of the laser chamber. The laser chamber is configured to cause light, generated through excitation of the laser gas due to discharge caused by a voltage applied between the first electrode and the second electrode, to be output outside the laser chamber through the pair of windows. The first electrode includes a contact region which is in contact with the surface of the electrical insulating portion, an opposing surface which faces the second electrode, and a first curved surface which is included in a region between the contact region and the opposing surface and which is convexly curved toward an outer side of the first electrode. In a cross section of the first electrode along a surface extending in a separation direction of the first electrode and the second electrode and a predetermined direction perpendicular to the separation direction, the contact region is located on an inner side of the first electrode with respect to the first curved surface, and the first curved surface is a part of a circumference of a circle or an ellipse which does not intersect the electrical insulating portion.

An electronic device manufacturing method according to an aspect of the present disclosure includes generating laser light using a gas laser device, outputting the laser light to an exposure apparatus, and exposing a photosensitive substrate to the laser light in the exposure apparatus to manufacture an electronic device. Here, the gas laser device includes a conductive laser chamber including an opening and a pair of windows, an electrical insulating portion blocking the opening, a first electrode fixed to a surface of the electrical insulating portion on a side of an internal space of the laser chamber, and a second electrode facing the first electrode at the internal space of the laser chamber. A laser gas is enclosed at the internal space of the laser chamber. The laser chamber is configured to cause light, generated through excitation of the laser gas due to discharge caused by a voltage applied between the first electrode and the second electrode, to be output outside the laser chamber through the pair of windows. The first electrode includes a contact region which is in contact with the surface of the electrical insulating portion, an opposing surface which faces the second electrode, and a first curved surface which is included in a region between the contact region and the opposing surface and which is convexly curved toward an outer side of the first electrode. In a cross section of the first electrode along a surface extending in a separation direction of the first electrode and the second electrode and a predetermined direction perpendicular to the separation direction, the contact region is located on an inner side of the first electrode with respect to the first curved surface, and the first curved surface is a part of a circumference of a circle or an ellipse which does not intersect the electrical insulating portion.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire gas laser device of a comparative example.

FIG. 3 is a sectional view, perpendicular to a travel direction of laser light, of a laser chamber of the comparative example.

FIG. 4 is a sectional view, perpendicular to the travel direction of laser light, of the laser chamber of a first embodiment.

FIG. 5 is an enlarged view of a region surrounded by broken lines shown in FIG. 4.

FIG. 6 is a sectional view, perpendicular to the travel direction of laser light, of the laser chamber of a second embodiment.

FIG. 7 is an enlarged view of a region surrounded by broken lines shown in FIG. 6.

FIG. 8 is a top view of an end side of an electrode.

FIG. 9 is a sectional view of the end side shown in FIG. 8.

FIG. 10 is a sectional view, perpendicular to the travel direction of laser light, of the laser chamber of a third embodiment.

FIG. 11 is a sectional view, perpendicular to the travel direction of laser light, of the laser chamber of a fourth embodiment.

### DESCRIPTION OF EMBODIMENTS

1. Description of electronic device manufacturing apparatus used in exposure process for electronic device
2. Description of gas laser device of comparative example 2.1 Configuration
   2.2 Operation
   2.3 Problem
3. Description of gas laser device of first embodiment
   3.1 Configuration
   3.2 Effect
4. Description of gas laser device of second embodiment
   4.1 Configuration
   4.2 Effect
5. Description of gas laser device of third embodiment
   5.1 Configuration
   5.2 Effect
6. Description of gas laser device of fourth embodiment
   6.1 Configuration
   6.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.
1. Description of electronic device manufacturing apparatus used in exposure process for electronic device

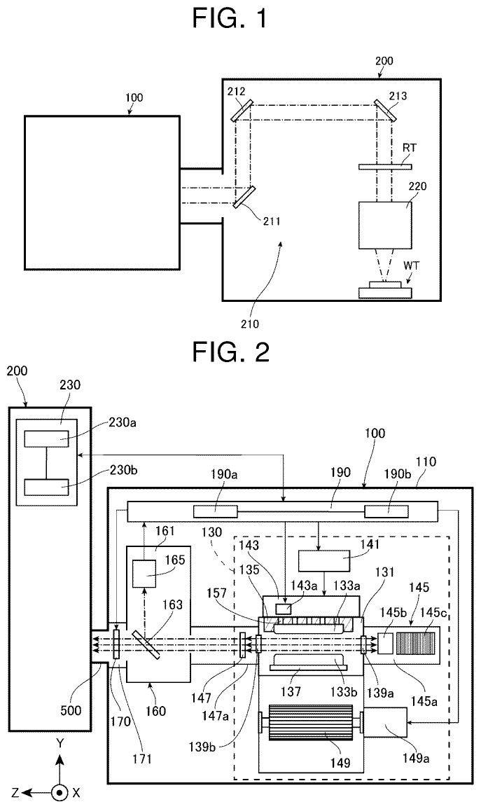

FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.
2. Description of gas laser device of comparative example
   2.1 Configuration

The gas laser device 100 of a comparative example will be described. The comparative example of the present disclosure is an example recognized by the applicant as known only by the applicant, and is not a publicly known example admitted by the applicant.

FIG. 2 is a schematic view showing a schematic configuration example of the entire gas laser device 100 of the comparative example. The gas laser device 100 is, for example, an ArF excimer laser device using a mixed gas including argon (Ar), fluorine (F₂), and neon (Ne). The gas laser device 100 outputs laser light having a center wavelength of about 193 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248 nm. The mixed gas containing Ar, F₂, and Ne which is a laser medium and the mixed gas containing Kr, F₂, and Ne which is a laser medium may be referred to as a laser gas.

The gas laser device 100 includes a housing 110, and a laser oscillator 130, a monitor module 160, a shutter 170, and a laser processor 190 arranged at the internal space of the housing 110 as a main configuration.

The laser oscillator 130 includes a laser chamber 131, a charger 141, a pulse power module 143, a line narrowing module 145, and an output coupling mirror 147. In FIG. 2, the internal configuration of the laser chamber 131 is shown as viewed from a direction substantially perpendicular to the travel direction of the laser light.

The laser chamber 131 is electrically conductive and grounded. Examples of the material of the laser chamber 131 include a metal such as nickel-plated aluminum and nickel-plated stainless steel. The laser chamber 131 includes an internal space in which light is generated by excitation of a laser medium in the laser gas. This light travels to windows 139a, 139b described later. The laser gas is supplied from a laser gas supply source (not shown) to the internal space of the laser chamber 131 through a pipe (not shown). Further, the laser gas in the laser chamber 131 is subjected to a process of removing Fe gas by a halogen filter or the like, and is exhausted to the housing 110 through a pipe (not shown) by an exhaust pump (not shown).

At the internal space of the laser chamber 131, an electrode 133a which is a first electrode and an electrode 133b which is a second electrode are spaced apart from and opposed to each other, and each longitudinal direction is along the travel direction of the light. In the following, the longitudinal direction of the electrodes 133a, 133b may be referred to as a Z direction, the direction which is perpendicular to the Z direction and in which the electrodes 133a, 133b are juxtaposed and the electrodes 133a, 133b are separated from each other may be referred to as a Y direction, and the direction perpendicular to the Y direction and the Z direction may be referred to as an X direction. The electrodes 133a, 133b are discharge electrodes for exciting the laser medium by glow discharge. In the present example, the electrode 133a is the cathode and the electrode 133b is the anode.

The electrode 133a is fixed to a plate-shaped electrical insulating portion 135 by a conductive member 157 which is, for example, a bolt. The conductive member 157 is electrically connected to the pulse power module 143, and applies a high voltage from the pulse power module 143 to the electrode 133a. The electrode 133b is supported by and electrically connected to an electrode holder portion 137.

The charger 141 is a DC power source device that charges a charging capacitor (not shown) in the pulse power module 143 with a predetermined voltage. The pulse power module 143 includes a switch 143a controlled by the laser processor 190. When the switch 143a is turned ON from OFF, the pulse power module 143 generates a pulse high voltage from the electric energy held in the charger 141 and applies the high voltage between the electrode 133a and the electrode 133b.

When the high voltage is applied between the electrode 133a and the electrode 133b, discharge occurs between the electrode 133a and the electrode 133b. The laser medium in the laser chamber 131 is excited by the energy of the discharge, and the excited laser medium emits light when shifting to the ground state.

The laser chamber 131 is provided with a pair of windows 139a, 139b. The window 139a is located at one end side of the laser chamber 131 in the travel direction of the laser light, the window 139b is located at the other end side in the travel direction, and the windows 139a, 139b sandwich a space between the electrode 133a and the electrode 133b. The windows 139a, 139b are inclined at the Brewster angle with respect to the travel direction of the laser light so that P-polarized light of the laser light is suppressed from being reflected. The laser light oscillated as described later is output to the outside of the laser chamber 131 through the windows 139a, 139b. Since a pulse high voltage is applied between the electrode 133a and the electrode 133b by the pulse power module 143 as described above, the laser light is pulse laser light.

The line narrowing module 145 includes a housing 145a, and a prism 145b, a grating 145c, and a rotation stage (not shown) arranged at the internal space of the housing 145a. An opening is formed in the housing 145a, and the housing 145a is connected to the rear side of the laser chamber 131 through the opening.

The prism 145b expands the beam width of the light output from the window 139a and causes the light to be incident on the grating 145c. Further, the prism 145b also reduces the beam width of the reflection light from the grating 145c and returns the light to the internal space of the laser chamber 131 through the window 139a. The prism 145b is supported by the rotation stage and is rotated by the rotation stage. The incident angle of the light with respect to the grating 145c is changed by the rotation of the prism 145b. Therefore, by rotating the prism 145b, the wavelength of the light returning from the grating 145c to the laser chamber 131 via the prism 145b can be selected. Although FIG. 2 shows an example in which one prism 145b is arranged, at least one prism may be arranged.

The surface of the grating 145c is configured of a material having a high reflectance, and a large number of grooves are formed on the surface at predetermined intervals. The shape of the cross section of each groove is, for example, a right triangle. The light incident on the grating 145c from the prism 145b is reflected by these grooves and diffracted in a direction corresponding to the wavelength of the light. The grating 145c is arranged in the Littrow arrangement, which causes the incident angle of the light incident on the grating 145c from the prism 145b to coincide with the diffraction angle of the diffracted light having a desired wavelength. Thus, light having a wavelength close to the desired wavelength returns into the laser chamber 131 via the prism 145b.

The output coupling mirror 147 is arranged at the internal space of the optical path pipe 147a connected to the other end side of the laser chamber 131, and faces the window 139b. The output coupling mirror 147 transmits a part of the laser light output from the window 139b toward the monitor module 160, and reflects another part of the laser light to return to the internal space of the laser chamber 131 through the window 139b. Thus, the grating 145c and the output coupling mirror 147 configure a Fabry-Perot laser resonator, and the laser chamber 131 is arranged on the optical path of the laser resonator.

The monitor module 160 is arranged on the optical path of the laser light output from the output coupling mirror 147. The monitor module 160 includes a housing 161, and a beam splitter 163 and an optical sensor 165 arranged at the internal space of the housing 161. An opening is formed in the housing 161, and the internal space of the housing 161 communicates with the internal space of the optical path pipe 147a through the opening.

The beam splitter 163 transmits a part of the laser light output from the output coupling mirror 147 toward the shutter 170, and reflects another part of the laser light toward a light receiving surface of the optical sensor 165. The optical sensor 165 measures an energy E of the laser light incident on the light receiving surface. The optical sensor 165 outputs a signal indicating the measured energy E to the laser processor 190.

The laser processor 190 of the present disclosure is a processing device including a storage device 190a in which a control program is stored and a central processing unit (CPU) 190b that executes the control program. The laser processor 190 is specifically configured or programmed to perform various processes included in the present disclosure. The laser processor 190 controls the entire gas laser device 100.

The laser processor 190 transmits and receives various signals to and from an exposure processor 230 of the exposure apparatus 200. For example, the laser processor 190 receives a later-described light emission trigger Tr and a later-described target energy Et from the exposure processor 230. The target energy Et is a target value of the energy of the laser light used in the exposure process. The laser processor 190 controls the charge voltage of the charger 141 based on the energy E and the target energy Et received from the optical sensor 165 and the exposure processor 230. By controlling the charge voltage, the energy of the laser light is controlled. Further, the laser processor 190 transmits a command signal of ON or OFF of the switch 143a to the pulse power module 143. The laser processor 190 is electrically connected to the shutter 170 and controls opening and closing of the shutter 170.

The laser processor 190 closes the shutter 170 until a difference ΔE between the energy E received from the monitor module 160 and the target energy Et received from the exposure processor 230 falls within an allowable range. When the difference ΔE falls within the allowable range, the laser processor 190 transmits, to the exposure processor 230, a reception preparation completion signal indicating that exposure preparation of the light emission trigger Tr is completed. The exposure processor 230 transmits a signal indicating the light emission trigger Tr to the laser processor 190 when receiving the reception preparation completion signal, and the laser processor 190 opens the shutter 170 when receiving the signal indicating the light emission trigger Tr. The light emission trigger Tr is defined by a predetermined repetition frequency f and a predetermined number of pulses P of the laser light, is a timing signal for the exposure processor 230 to cause the laser oscillator 130 to perform laser oscillation, and is an external trigger. The repetition frequency f of the laser light is, for example, 100 Hz or more and 10 kHz or less.

The shutter 170 is arranged on the optical path of the laser light having passed through an opening formed on the side of the housing 161 of the monitor module 160 opposite to the side to which the optical path pipe 147a is connected. The shutter 170 is arranged at the internal space of the optical path pipe 171. The optical path pipe 171 is connected to the housing 161 to surround the opening and is in communication with the housing 161. The internal spaces of the optical path pipe 171 and the optical path pipe 147a and the internal spaces of the housing 161 and the housing 145a are supplied and filled with a purge gas. The purge gas includes an inert gas such as nitrogen (N₂). The purge gas is supplied from a purge gas supply source (not shown) through a pipe (not shown). The optical path pipe 171 is in communication with the exposure apparatus 200 through the opening of the housing 110 and the optical path pipe 500 connecting the housing 110 and the exposure apparatus 200. The laser light having passed through the shutter 170 enters the exposure apparatus 200.

The exposure processor 230 of the present disclosure is a processing device including a storage device 230a in which a control program is stored and a CPU 230b which executes the control program. The exposure processor 230 is specifically configured or programmed to perform various processes included in the present disclosure. Further, the exposure processor 230 controls the entire exposure apparatus 200.

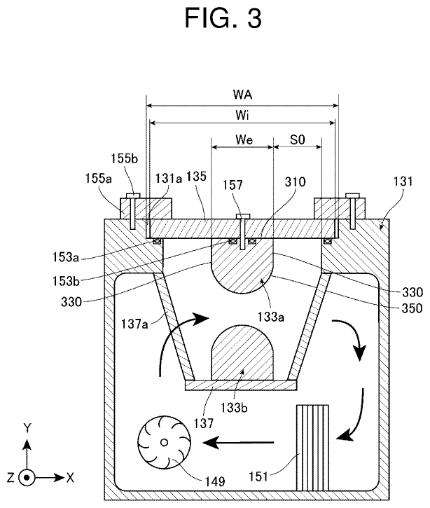

FIG. 3 is a sectional view, perpendicular to the travel direction of the laser light, of the laser chamber 131 of the comparative example. In FIG. 3, the components in the laser chamber 131 are shown in an XY cross section. A cross flow fan 149 and a heat exchanger 151 are further arranged at the internal space of the laser chamber 131.

The cross flow fan 149 and the heat exchanger 151 are arranged at the internal space of the laser chamber 131 on the side opposite to the electrode 133b with respect to the electrode holder portion 137. At the internal space of the laser chamber 131, the space in which the cross flow fan 149 and the heat exchanger 151 are arranged is in communication with the space between the electrodes 133a, 133b. The heat exchanger 151 is arranged beside the cross flow fan 149, and is connected to a pipe (not shown) through which a cooling medium being a liquid flows. The cooling medium may be a gas. As shown in FIG. 2, the cross flow fan 149 is connected to a motor 149a arranged outside the laser chamber 131, and rotates with rotation of the motor 149a. As the cross flow fan 149 rotates, the laser gas enclosed at the internal space of the laser chamber 131 circulates as indicated by bold arrows in FIG. 3. That is, the laser gas circulates through the cross flow fan 149, a space between the electrode 133a and the electrode 133b, the heat exchanger 151, and the cross flow fan 149 in this order. At least a part of the circulating laser gas passes through the heat exchanger 151, and the temperature of the laser gas is adjusted by the heat exchanger 151. ON/OFF and the number of revolution of the motor 149a are adjusted by the control of the laser processor 190. Accordingly, the laser processor 190 can adjust the circulation speed of the laser gas circulating through the internal space of the laser chamber 131 by controlling the motor 149a.

The electrode holder portion 137 is electrically connected to the laser chamber 131 via wires 137a. The electrode 133b supported by the electrode holder portion 137 is connected to the ground potential via the electrode holder portion 137, the wires 137a, and the laser chamber 131.

A preionization electrode (not shown) is provided on the electrode holder portion 137. The preionization electrode includes an inner electrode, an outer electrode, and a dielectric. The inner electrode is connected to the pulse power module 143 via a wire (not shown). The outer electrode is electrically connected to the electrode 133b via the electrode holder portion 137, and is electrically connected to the laser chamber 131 via the electrode holder portion 137 and the wires 137a. Therefore, the outer electrode is connected to the ground potential via the electrode holder portion 137, the wires 137a, and the laser chamber 131. The dielectric is made of, for example, aluminum oxide, and is arranged between the inner electrode and the outer electrode. When a high voltage is applied from the pulse power module 143 to the inner electrode and the outer electrode, corona discharge occurs in the vicinity of the dielectric and the outer electrode. The corona discharge assists stable generation of glow discharge which occurs between the electrodes 133a, 133b.

The electrical insulating portion 135 includes an insulator. Examples of the electrical insulating portion 135 include alumina ceramics having low reactivity with an F-gas. The electrical insulating portion 135 may have electrical insulation, and the material of the electrical insulating portion 135 may be a resin such as a phenol resin and a fluoro-resin, or quartz, glass, or the like.

The electrical insulating portion 135 blocks an opening 131a provided in the laser chamber 131. Further, the electrical insulating portion 135 is fixed to the laser chamber 131 by clamps 155a and bolts 155b. A groove is provided in a part of the laser chamber 131 facing the outer edge of the electrical insulating portion 135, and a sealing member 153a is arranged in the groove. The sealing member 153a is deformed to be compressed by the pressing force from the electrical insulating portion 135. The sealing member 153a is brought into close contact with the inner surfaces of the electrical insulating portion 135 and the groove by deformation, and fills the gap between the electrical insulating portion 135 and the groove, thereby performing sealing between the electrical insulating portion 135 and the laser chamber 131. By the sealing member 153a, leakage of the laser gas from the internal space of the laser chamber 131 through the opening 131a is suppressed. The sealing member 153a is, for example, an O-ring made of fluoro-rubber or a metal seal.

The electrode 133a is fixed to a surface of the electrical insulating portion 135 on the internal space side of the laser chamber 131 by the conductive member 157.

The electrode 133a includes a contact region 310, an opposing surface 350, and regions 330 between the contact region 310 and the opposing surface 350. The contact region 310 is located on the planar upper surface of the electrode 133a and in contact with the surface of the electrical insulating portion 135 on the internal space side of the laser chamber 131. Each of the regions 330 includes a plane being perpendicular to the contact region 310 and extending toward the electrode 133b, and is spaced from the chamber inner wall surface facing the region 330. The region 330 is connected to the contact region 310 and the opposing surface 350. The opposing surface 350 is a discharge surface facing the electrode 133b, and is curved convexly toward the electrode 133b. The curvature of the opposing surface 350 is defined by a predetermined function.

An opposing surface of the electrode 133b facing the opposing surface 350 is curved convexly toward the electrode 133a, and the curvature of the opposing surface is also defined by a predetermined function.

In FIG. 3, the width of the electrical insulating portion 135 in the X direction is shown as Wi, and the width of the opening 131a is shown as WA. The width Wi is slightly shorter than the width WA but may be approximately the same as the width WA. Further, in FIG. 3, the maximum width of the electrode 133a in the X direction is shown as We, being the distance from the region 330 on the left side to the region 330 on the right side, and the maximum width We is shorter than the width Wi. Further, in the X direction, the edge of the electrical insulating portion 135 is located outside the projection surface of the electrode 133a in the Y direction. In FIG. 3, the distance from the electrode 133a to the chamber inner wall surface in the X direction is shown as a creepage distance S0. The creepage distance S0 is longer than the minimum distance from the electrode 133a to the electrode 133b.

A groove is provided at the contact region 310 around the conductive member 157 and a sealing member 153b is arranged in the groove. The sealing member 153b is deformed to be compressed by the pressing force from the electrical insulating portion 135. The sealing member 153b is brought into close contact with the inner surfaces of the electrical insulating portion 135 and the groove by deformation, and fills the gap between the electrical insulating portion 135 and the groove, thereby performing sealing between the electrical insulating portion 135 and the electrode 133a. By the sealing member 153b, leakage of the laser gas from the internal space of the laser chamber 131 through a hole in the electrical insulating portion 135 through which the conductive member 157 passes is suppressed. Examples of the sealing member 153b include the same configuration as that of the sealing member 153a.
2.2 Operation

Next, operation of the gas laser device 100 of the comparative example will be described.

Before the gas laser device 100 outputs the laser light, the internal spaces of the optical path pipes 147a, 171, 500 and the internal spaces of the housings 145a, 161 are filled with a purge gas from the purge gas supply source (not shown). Further, a laser gas is supplied to the internal space of the laser chamber 131 from a laser gas supply source (not shown). When the laser gas is supplied, the laser processor 190 controls the motor 149a to rotate the cross flow fan 149. By the rotation of the cross flow fan 149, the laser gas circulates through the internal space of the laser chamber 131.

Before the gas laser device 100 outputs the laser light, the laser processor 190 receives a signal indicating the target energy Et and a signal indicating the light emission trigger Tr from the exposure processor 230. Upon receiving the signal indicating the target energy Et, the laser processor 190 closes the shutter 170 and drives the charger 141. Further, the laser processor 190 turns ON the switch 143a of the pulse power module 143. Thus, the pulse power module 143 applies a pulse high voltage from the electric energy held in the charger 141 between the electrode 133a and the electrode 133b and between the inner electrode and the outer electrode. Here, the timing at which the high voltage is applied between the inner electrode and the outer electrode is slightly earlier than the timing at which the high voltage is applied between the electrode 133a and the electrode 133b. When the high voltage is applied between the inner electrode and the outer electrode, corona discharge occurs in the vicinity of the dielectric, and ultraviolet light is emitted. When the laser gas between the electrode 133a and the electrode 133b is irradiated with the ultraviolet light, the laser gas between the electrode 133a and the electrode 133b undergoes preionization. After the preionization, when the high voltage is applied between the electrode 133a and the electrode 133b, discharge occurs between the electrode 133a and the electrode 133b. Then, the laser medium contained in the laser gas between the electrode 133a and the electrode 133b is brought into an excited state, and light is emitted when the laser medium returns to the ground state. The light resonates between the grating 145c and the output coupling mirror 147, and is amplified every time it passes through the discharge space at the internal space of the laser chamber 131, thereby causing laser oscillation. Then, a part of the laser light is transmitted through the output coupling mirror 147 as pulse laser light and travels to the beam splitter 163.

A part of the laser light traveling to the beam splitter 163 is reflected by the beam splitter 163 and received by the optical sensor 165. The optical sensor 165 measures the energy E of the received laser light, and outputs a signal indicating the energy E to the laser processor 190. The laser processor 190 controls the charge voltage so that the difference ΔE between the energy E and the target energy Et falls within the allowable range, and after the difference ΔE falls within the allowable range, the laser processor 190 transmits, to the exposure processor 230, the reception preparation completion signal indicating that reception preparation of the light emission trigger Tr is completed.

Upon receiving the reception preparation completion signal, the exposure processor 230 transmits the light emission trigger Tr to the laser processor 190. When the laser processor 190 opens the shutter 170 in synchronization with the reception of the light emission trigger Tr, the laser light that has passed through the shutter 170 enters the exposure apparatus 200. The laser light is, for example, pulse laser light having a center wavelength of 193 nm.

Due to circulation of the laser gas, impurities of the gas generated by discharge between the electrode 133a and the electrode 133b move downstream, and a fresh laser gas is supplied between the electrode 133a and the electrode 133b for subsequent discharge. Further, when the laser gas passes through the heat exchanger 151, heat caused by discharge is removed, and increase in temperature of the laser gas is suppressed.
2.3 Problem

In the gas laser device 100 of the comparative example, to achieve high output of the laser light output from the gas laser device 100, generally, a higher high voltage is applied between the electrode 133a and the electrode 133b. When a higher high voltage is applied, it is required to increase the creepage distance S0 so that the creepage distance S0 is secured while suppressing generation of corona discharge associated with the application to prevent a short circuit with the conductive laser chamber 131. To increase the creepage distance S0, the width Wi of the electrical insulating portion 135 may be increased. However, increasing the width Wi increases the width WA of the opening 131a in which the electrical insulating portion 135 is arranged. As the width WA increases, the strength of the laser chamber 131 decreases, and the laser chamber 131 may be deformed by the laser gas enclosed at the internal space of the laser chamber 131. Further, due to the deformation of the laser chamber 131, the travel direction of the laser light output from the laser chamber 131 may change from a previously assumed travel direction. Due to this change, there arises a concern that the laser light satisfying the performance required by the exposure apparatus 200 is not output, and the reliability of the gas laser device 100 is decreased.

Therefore, in each of the following embodiments, the gas laser device 100 capable of suppressing a decrease in reliability will be exemplified.
3. Description of gas laser device of first embodiment

Next, the gas laser device 100 of a first embodiment will be described. Any component same as that described above is denoted by an identical reference sign, and duplicate description thereof is omitted unless specific description is needed.
3.1 Configuration

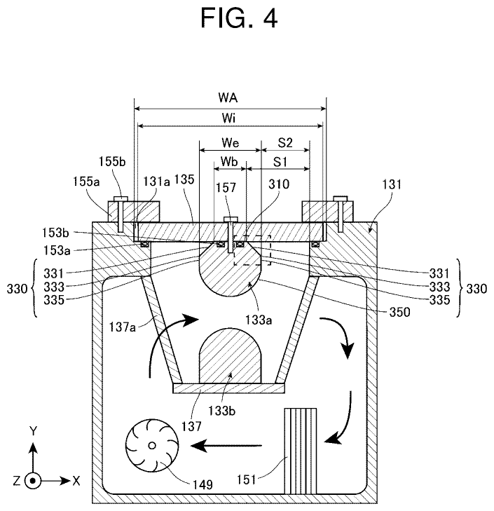

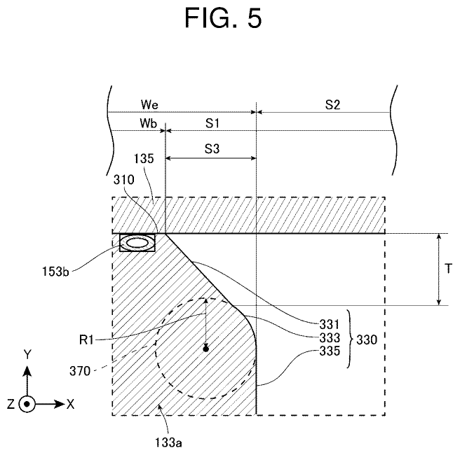

FIG. 4 is a sectional view, perpendicular to the travel direction of the laser light, of the laser chamber 131 of the present embodiment. FIG. 5 is an enlarged view of a region surrounded by broken lines shown in FIG. 4. In the gas laser device 100 of the present embodiment, the configuration of the electrode 133a differs from the configuration of the electrode 133a of the comparative embodiment.

Each of the regions 330 of the electrode 133a includes a first plane 331, a first curved surface 333, and a second plane 335.

The first plane 331 is connected to the edge of the contact region 310 and extends away from the electrical insulating portion 135. The first plane 331 of the present embodiment is inclined with respect to the contact region 310 and is connected to the first curved surface 333. A space in contact with the electrical insulating portion 135, the first plane 331, and the first curved surface 333 is provided along the Z direction.

The first curved surface 333 is located between the first plane 331 and the second plane 335 and is connected to each thereof. A part of the first curved surface 333 is located on the outermost side of the electrode 133a. The part is a contact point of the first curved surface 333 connected to the second plane 335. The first curved surface 333 is convexly curved toward the outer side of the electrode 133a. In the XY cross section of the electrode 133a shown in FIG. 5, the first curved surface 333 is a part of the circumference of a circle 370. The center of the circle 370 is located inside the electrode 133a. The circle 370 does not intersect the electrical insulating portion 135.

A radius R1 of the circle 370 is preferably 5 mm or more. The radius R1 is, for example, a radius at which, when the distance from the cylindrical electrode to the grounded flat plate electrode is 30 mm and a voltage of −28 kV is applied to the cylindrical electrode, the electric field intensity on the surface of the cylindrical electrode becomes 3 kV/mm or less, and corona discharge is presumed to be suppressed.

The second plane 335 extends in the Y direction and is connected to the first curved surface 333 and the opposing surface 350. The second plane 335 is located on the outermost side of the electrode 133a. The maximum width We in the present embodiment is the distance from the second plane 335 on the left side of the electrode 133a to the second plane 335 on the right side thereof. Here, it is also possible that the first curved surface 333 is connected to the opposing surface 350 without providing the second plane 335. In this case, the maximum width We is the distance from the contact point between the first curved surface 333 on the left side and the opposing surface 350 to the contact point between the first curved surface 333 on the right side and the opposing surface 350.

In the XY cross section of the electrode 133a along the surface extending in the Y direction and the X direction which is the predetermined direction, the contact region 310 is located on the inner side of the electrode 133a with respect to the first curved surface 333. Accordingly, the contact region 310 is further away from the chamber inner wall surface and the outer edge of the electrical insulating portion 135 than the first curved surface 333. The first curved surface 333 is further away from a line (not shown) extending in the Y direction and passing through the centers of the electrode 133a and the electrode 133b than the edge of the contact region 310. The contact region 310 is inside the projection surface of the electrode 133a with respect to the surface of the electrical insulating portion 135 on the internal space side of the laser chamber 131 in the Y direction, and the width Wb of the contact region 310 in the X direction is set to be shorter than the maximum width We.

In FIGS. 4 and 5, the distance from the edge of the contact region 310 to the chamber inner wall surface facing the edge is shown as a creepage distance S1. The creepage distance S1 is longer than a minimum distance S2 from the second plane 335 of the electrode 133a to the chamber inner wall surface. The minimum distance S2 corresponds to the creepage distance S0 of the comparative example.

Here, for example, description will be provided on a case in which a voltage of 30 kV or less is applied between the electrode 133a and the electrode 133b, the minimum distance S2 is 25 mm or more and 36 mm or less, and the maximum width We is 20 mm or more and 25 mm or less. In this case, for example, a minimum distance T between the first curved surface 333 and the electrical insulating portion 135 in the Y direction is 2 mm or more, and the width Wb is 10 mm or more and 20 mm or less. Further, for example, the creepage distance S1 is 40 mm or more and 65 mm or less, a distance S3 which is the difference between the minimum distance S2 and the creepage distance S1 is approximately 2.5 mm, and the radius R1 is 5 mm or more. The distance S3 is also a distance in the X direction from a contact point between the contact region 310 and the first plane 331 to a contact point between the first curved surface 333 and the second plane 335.

The electrode 133a and the electrode 133b of the present embodiment are formed of a metal such as copper, brass, tungsten alloy, and nickel alloy.
3.2 Effect

In the gas laser device 100 of the present embodiment, as in the comparative example, since the electrical insulating portion 135 blocks the opening 131a, the internal space of the laser chamber 131 is sealed. In the internal space at which the laser gas is enclosed, a voltage is applied between the opposing surface 350 of the electrode 133a and the electrode 133b, so that light generated from the laser gas is output to the outside of the laser chamber 131 through a pair of windows.

In the XY cross section of the electrode 133a being the first electrode in the present embodiment, the contact region 310 is located on the inner side of the electrode 133a with respect to the first curved surface 333. Therefore, the creepage distance S1 from the edge of the contact region 310 to the chamber inner wall surface may be longer than that when the contact region 310 is located on the outer side of the electrode 133a with respect to the first curved surface 333. Therefore, even when a voltage is applied between the opposing surface 350 of the electrode 133a and the electrode 133b, creeping discharge can be suppressed, and a short circuit with the laser chamber 131 can be suppressed. Further, it is possible to suppress the width Wi of the electrical insulating portion 135 from being increased by the length from the edge of the contact region 310 to the first curved surface 333, that is, the distance S3, and it is possible to suppress the width WA of the opening 131a in which the electrical insulating portion 135 is arranged from being increased. Accordingly, a decrease in strength of the laser chamber 131 can be suppressed, and the deformation of the laser chamber 131 caused by the laser gas can be suppressed. Therefore, it is possible to suppress the travel direction of the laser light output from the laser chamber 131 from being changed from a previously-assumed travel direction. Further, in the above configuration, in the XY cross section of the electrode 133a, the first curved surface 333 is a part of the circumference of the circle 370 that does not intersect the electrical insulating portion 135. Therefore, since the creepage distance S1 can be secured longer than that when the circle 370 intersects the electrical insulating portion 135, creepage discharge can be suppressed. Therefore, the laser light: satisfying the performance required by the exposure apparatus 200 can be output, and a decrease in reliability of the gas laser device 100 can be suppressed.

Further, the first plane 331 of the region 330 is inclined with respect to the contact region 310 and connected to the first curved surface 333 as extending in the direction away from the electrical insulating portion 135. According to the above configuration, the creepage distance S1 can be increased by an amount corresponding to the distance S3, whereby creepage discharge between the electrode 133a and the laser chamber 131 can be suppressed.

The region 330 further includes the second plane 335 extending in the direction in which the electrode 133a and the electrode 133b are separated and connected to the first curved surface 333 and the opposing surface 350. According to the above configuration, compared to the case in which the second plane 335 extends toward the chamber inner wall surface facing the second plane 335, the second plane 335 may be away from the chamber inner wall surface, and the electric field may be relaxed between the second plane 335 and the chamber inner wall surface facing the second plane 335.

Further, in the electrode 133a, the first curved surface 333 can suppress unnecessary discharge generated from a corner part as compared with the case in which a corner part is provided at the contact point between the first plane 331 and the second plane 335 where the first curved surface 333 is provided.

Further, in the XY cross section of the electrode 133a, the X direction is the predetermined direction in the present configuration. The predetermined direction is a direction parallel to a surface of the electrical insulating portion 135 on the internal space side of the laser chamber 131 and perpendicular to the longitudinal direction of the electrode 133a. Further, the predetermined direction is a direction perpendicular to the separation direction of the electrode 133a and the electrode 133b and the longitudinal direction of the electrode 133a which which is perpendicular to the separation direction.

According to the above configuration, the creepage distance S1 in the predetermined direction can be increased at the end part of the electrode 133a in the predetermined direction, whereby creepage discharge can be suppressed.
4. Description of gas laser device of second embodiment

Next, the gas laser device 100 of a second embodiment will be described. Any component same as that described above is denoted by an identical reference sign, and duplicate description thereof is omitted unless specific description is needed.
4.1 Configuration

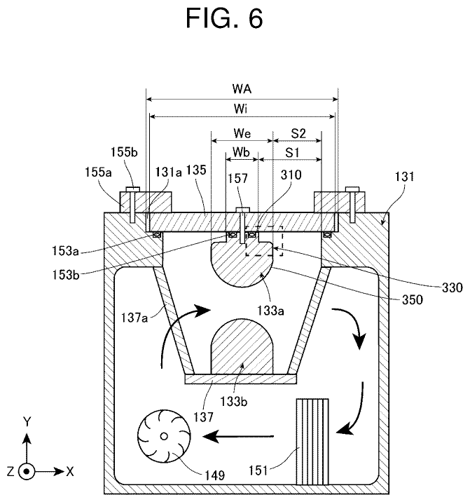

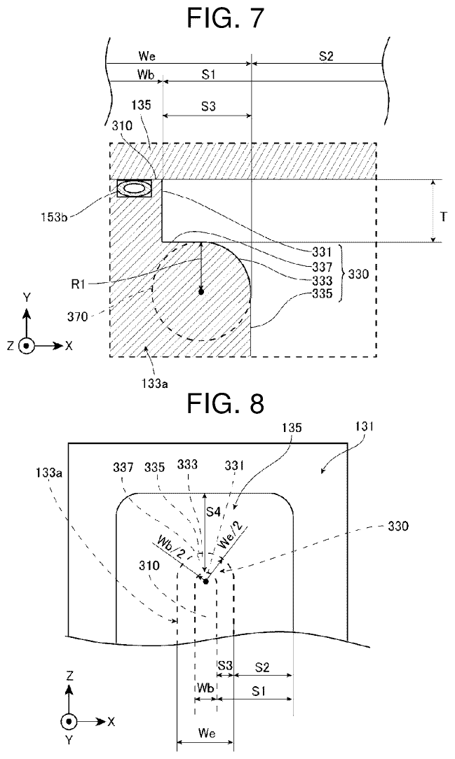

FIG. 6 is a sectional view, perpendicular to the travel direction of the laser light, of the laser chamber 131 of the present embodiment. FIG. 7 is an enlarged view of a region surrounded by broken lines shown in FIG. 6. In the gas laser device 100 of the present embodiment, the configuration of the electrode 133a differs from the configuration of the electrode 133a of the first embodiment.

The first plane 331 of the present embodiment is perpendicular to the contact region 310.

Each of the regions 330 of the present embodiment further includes a third plane 337 connected to the first plane 331 and the first curved surface 333 and parallel to the surface of the electrical insulating portion 135 on the internal space side of the laser chamber 131. Since the third plane 337 is parallel to the surface of the electrical insulating portion 135 on the internal space side of the laser chamber 131, the distance T from the third plane 337 to the electrical insulating portion 135 is constant. The distance T is also the length of the first plane 331 in the Y direction. For example, the distance T is 2 mm or more, and may be longer than the radius R1 or equal to or less than the radius R1, or may be longer than the distance S3 or equal to or less than the distance S3.

A space in contact with the electrical insulating portion 135, the first plane 331, the third plane 337, and the first curved surface 333 is provided along the Z direction.
4.2 Effect

The region 330 of the electrode 133a of the present embodiment further includes the first plane 331 connected to the contact region 310 and extending away from the electrical insulating portion 135 and the third plane 337 connected to the first plane 331 and the first curved surface 333 and parallel to the surface of the electrical insulating portion 135 on the internal space side of the laser chamber 131.

According to the above configuration, the space in contact with the electrical insulating portion 135, the first plane 331, the first curved surface 333, and the third plane 337 may be wider than the space in contact with the electrical insulating portion 135, the first plane 331, and the first curved surface 333 in the first embodiment. By widening the space, the region in which the creepage distance S1 is secured can be widened, and the electric field strength extending between the third plane 337 and the electrical insulating portion 135 can be suppressed, whereby the creepage discharge can be suppressed.

Here, the first plane 331 may be inclined and connected to the third plane 337 as in the first embodiment. The entire third plane 337 need not be parallel to the surface of the electrical insulating portion 135 on the internal space side of the laser chamber 131. A part of the third plane 337 may be parallel to the surface of the electrical insulating portion 135 on the internal space side of the laser chamber 131, and the other part thereof may be inclined with respect to the surface of the electrical insulating portion 135 on the internal space side of the laser chamber 131 while extending in a direction away from the electrical insulating portion 135. Alternatively, the entire third plane 337 may be inclined like the first plane 331 of the first embodiment.

Further, the first plane 331 is perpendicular to the contact region 310. According to the above configuration, as compared with the case in which the first plane 331 is inclined with respect to the contact region 310, corona discharge is less likely to occur, and the creepage distance S1 can be secured.

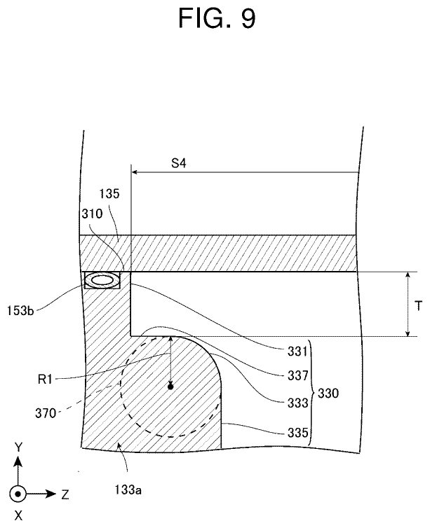

Next, a modification of the present embodiment will be described. FIG. 8 is a top view of the end side of the electrode 133a in the longitudinal direction of the electrode 133a. FIG. 9 is a sectional view of the end side shown in FIG. 8. In FIG. 9, the end side is shown in the YZ cross section.

Also at the end side of the electrode 133a of the modification, the region 330 includes the first curved surface 333, the second plane 335, and the third plane 337. In the YZ cross section of the electrode 133a along the surface extending in the Y direction and the Z direction which is the predetermined direction, the contact region 310 is located on the inner side of the electrode 133a with respect to the first curved surface 333 in the Z direction as well.

At the end part, the maximum outer radius of the second plane 335 is processed to be We/2 as shown in FIG. 8, but may be defined by an ellipse or another predetermined function. The end part of the contact region 310 and the maximum outer radius of the first plane 331 are also processed to be Wb/2 as shown in FIG. 8, but may be defined by an ellipse or another predetermined function. Further, as shown in FIG. 9, the distance T is secured also at the end part.

The creepage distance S4 in the Z direction from the edge of the contact region 310 to the chamber inner wall surface facing the edge may be equal to or more than the creepage distance S1 in the X direction. The creepage distance S4 need not be parallel to the Z direction, and may be the minimum distance in the Z direction from the edge of the contact region 310 to the chamber inner wall surface.

According to the above configuration, the creepage distance S4 in the Z direction being the predetermined direction can be increased at the end part of the electrode 133a in the Z direction as well, whereby creepage discharge in the Z direction can be suppressed.
5. Description of gas laser device of third embodiment

Next, the gas laser device 100 of a third embodiment will be described. Any component same as that described above is denoted by an identical reference sign, and duplicate description thereof is omitted unless specific description is needed.
5.1 Configuration

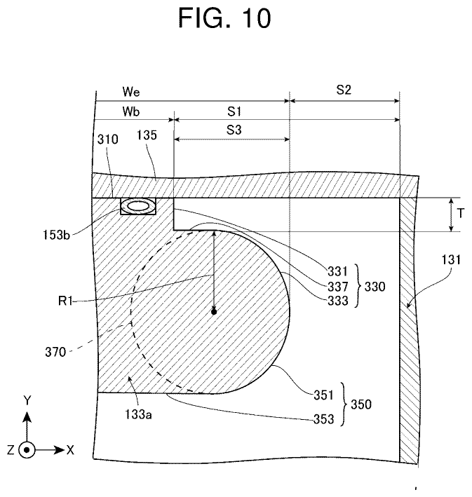

FIG. 10 is a sectional view, perpendicular to the travel direction of the laser light, of the laser chamber 131 of the present embodiment. In the gas laser device 100 of the present embodiment, the shape of the electrode 133a differs from the shape of the electrode 133a of the second embodiment.

In the electrode 133a of the present embodiment, the second plane 335 is not provided, the first curved surface 333 is connected to the opposing surface 350, and the opposing surface 350 includes a second curved surface 351 connected to the first curved surface 333 and a fourth plane 353 connected to the second curved surface 351. The second curved surface 351 is convexly curved toward the outer side of the electrode 133a. In the XY cross section of the electrode 133a shown in FIG. 10, the second curved surface 351 is a part of the circumference of the circle 370. Accordingly, the first curved surface 333 and the second curved surface 351 are located on the circumference of the circle 370. The contact point between the first curved surface 333 and the second curved surface 351 is located on the outermost side of the electrode 133a. The fourth plane 353 is parallel to the surface of the electrical insulating portion 135 on the internal space side of the laser chamber 131. For example, the radius R1 is longer than the distance T but may be shorter than the distance T and is longer than the distance S3 but may be equal to or less than the distance S3.
5.2 Effect

In the electrode 133a of the present embodiment, the opposing surface 350 includes the second curved surface 351 and the fourth plane 353, the first curved surface 333 and on the the second curved surface 351 are located circumference of the circle 370, and the fourth plane 353 is parallel to the surface of the electrical insulating portion 135 on the internal space side of the laser chamber 131. Accordingly, the shape of the electrode 133a is simplified and processing the electrode 133a can be facilitated. Further, since the curvature of the surface of the electrode 133a facing the inner wall surface of the laser chamber 131 can be increased, the insulating performance among the first curved surface 333, the second curved surface 351, and the chamber inner wall surface can be improved.

Further, the region 330 also includes the first plane 331 and the third plane 337. Accordingly, the shape of the electrode 133a is simplified and processing the electrode 133a can be facilitated.
6. Description of gas laser device of fourth embodiment

Next, the gas laser device 100 of a fourth embodiment will be described. Any component same as that described above is denoted by an identical reference sign, and duplicate description thereof is omitted unless specific description is needed.
6.1 Configuration

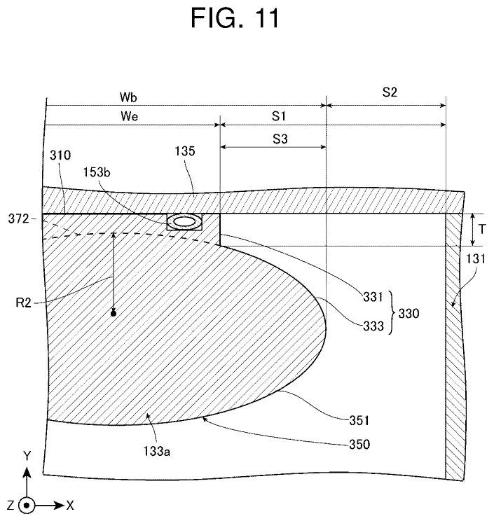

FIG. 11 is a sectional view, perpendicular to the travel direction of the laser light, of the laser chamber 131 of the present embodiment. In the gas laser device 100 of the present embodiment, the shape of the electrode 133a differs from the shape of the electrode 133a of the third embodiment.

In the electrode 133a of the present embodiment, the third plane 337 and the fourth plane 353 are not provided, and the first curved surface 333 is connected to the first plane 331 and the second curved surface 351 of the opposing surface 350. In the XY cross section of the electrode 133a shown in FIG. 11, the first curved surface 333 is a part of the circumference of an ellipse 372, and the second curved surface 351 is another part of the circumference of the ellipse 372. Accordingly, the first curved surface 333 and the second curved surface 351 are located on the circumference of the ellipse 372. The center of the ellipse 372 is located inside the electrode 133a. The minor axis of the ellipse 372 is along the Y direction, the major axis of the ellipse 372 is along the X direction, and a minor axis radius R2 of the ellipse 372 is along the separation direction and is longer than the distance T. The minor axis radius R2 may be shortened to be equal to or less than the distance T. The minor axis radius R2 may be longer than the distance S3 or equal to or less than the distance S3. The ellipse 372 does not intersect the electrical insulating portion 135. The first curved surface 333 and the second curved surface 351 are formed as a part of the circumference of the single ellipse 372, but may be formed as a part of the circumference of a single circle, or may be defined by a predetermined function.
6.2 Effect

In the XY cross section of the electrode 133a of the present embodiment, the first curved surface 333 is a part of the circumference of the ellipse 372, and the ellipse 372 does not intersect the electrical insulating portion 135. Therefore, the first curved surface 333 can be further separated from the electrical insulating portion 135 and creepage discharge can be suppressed as compared with the case in which the ellipse 372 intersects the electrical insulating portion 135.

Further, in the electrode 133a of the present embodiment, the first curved surface 333 and the second curved surface 351 are located on the circumference of the ellipse 372. Accordingly, the shape of the electrode 133a is simplified and processing the electrode 133a can be facilitated.

The region 330 of the electrode 133a of the present embodiment further includes the first plane 331 connected to the contact region 310, extending in the direction away from the electrical insulating portion 135 and perpendicular to the contact region 310, and connected to the first curved surface 333. Accordingly, the shape of the electrode 133a is simplified and processing the electrode 133a can be facilitated.

The description above is intended to be illustrative and the present disclosure is not limited thereto. Therefore, it would be obvious to those skilled in the art that various modifications to the embodiment of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device comprising:
a conductive laser chamber including an opening and a pair of windows;
an electrical insulating portion blocking the opening;
a first electrode fixed to a surface of the electrical insulating portion on a side of an internal space of the laser chamber; and
a second electrode facing the first electrode at the internal space of the laser chamber,
a laser gas being enclosed at the internal space of the laser chamber,
the laser chamber being configured to cause light, generated through excitation of the laser gas due to discharge caused by a voltage applied between the first electrode and the second electrode, to be output outside the laser chamber through the pair of windows,
the first electrode including a contact region which is in contact with the surface of the electrical insulating portion, an opposing surface which faces the second electrode, and a first curved surface which is included in a region between the contact region and the opposing surface and which is convexly curved toward an outer side of the first electrode, and
in a cross section of the first electrode along a surface extending in a separation direction of the first electrode and the second electrode and a predetermined direction perpendicular to the separation direction, the contact region being located on an inner side of the first electrode with respect to the first curved surface, and the first curved surface being a part of a circumference of a circle or an ellipse which does not intersect the electrical insulating portion.

2. The gas laser device according to claim 1,
wherein the region of the first electrode further includes a first plane connected to the contact region, extending in a direction away from the electrical insulating portion, and connected to the first curved surface.

3. The gas laser device according to claim 2,
wherein the first plane is inclined with respect to the contact region.

4. The gas laser device according to claim 1,
wherein the region of the first electrode further includes a second plane extending in the separation direction and connected to the first curved surface and the opposing surface.

5. The gas laser device according to claim 1,
wherein the first electrode extends in a travel direction of the light, and
the predetermined direction is a direction perpendicular to a longitudinal direction of the first electrode.

6. The gas laser device according to claim 1,
wherein the first electrode extends in a travel direction of the light, and
the predetermined direction is a longitudinal direction of the first electrode.

7. The gas laser device according to claim 1,
wherein the region of the first electrode further includes a first plane connected to the contact region and extending in a direction away from the electrical insulating portion, and a third plane connected to the first plane and the first curved surface and parallel to the electrical insulating portion.

8. The gas laser device according to claim 7,
wherein the region of the first electrode further includes a second plane extending in the separation direction and connected to the first curved surface and the opposing surface.

9. The gas laser device according to claim 7,
wherein the first plane is perpendicular to the contact region.

10. The gas laser device according to claim 1,
wherein the first curved surface is connected to the opposing surface.

11. The gas laser device according to claim 10,
wherein the opposing surface further includes a second curved surface connected to the first curved surface and a fourth plane connected to the second curved surface,
the first curved surface and the second curved surface are located on the circumference of the circle in the cross section of the first electrode, and
the fourth plane is parallel to the electrical insulating portion.

12. The gas laser device according to claim 11,
wherein the region of the first electrode further includes a first plane connected to the contact region and extending in a direction away from the electrical insulating portion, and a third plane connected to the first plane and the first curved surface and parallel to the electrical insulating portion.

13. The gas laser device according to claim 10,
wherein the opposing surface further includes a second curved surface connected to the first curved surface, and
the first curved surface and the second curved surface are located on the circumference of the ellipse in the cross section of the first electrode.

14. The gas laser device according to claim 13,
wherein the region of the first electrode further includes a first plane connected to the contact region, extending in a direction away from the electrical insulating portion and perpendicular to the contact region, and connected to the first curved surface.

15. An electronic device manufacturing method, comprising:
generating laser light using a gas laser device;
outputting the laser light to an exposure apparatus; and
exposing a photosensitive substrate to the laser light in the exposure apparatus to manufacture an electronic device,
the gas laser device comprising:
a conductive laser chamber including an opening and a pair of windows;
an electrical insulating portion blocking the opening;
a first electrode fixed to a surface of the electrical insulating portion on a side of an internal space of the laser chamber; and
a second electrode facing the first electrode at the internal space of the laser chamber,
a laser gas being enclosed at the internal space of the laser chamber,
the laser chamber being configured to cause light, generated through excitation of the laser gas due to discharge caused by a voltage applied between the first electrode and the second electrode, to be output outside the laser chamber through the pair of windows,
the first electrode including a contact region which is in contact with the surface of the electrical insulating portion, an opposing surface which faces the second electrode, and a first curved surface which is included in a region between the contact region and the opposing surface and which is convexly curved toward an outer side of the first electrode, and
in a cross section of the first electrode along a surface extending in a separation direction of the first electrode and the second electrode and a predetermined direction perpendicular to the separation direction, the contact region being located on an inner side of the first electrode with respect to the first curved surface, and the first curved surface being a part of a circumference of a circle or an ellipse which does not intersect the electrical insulating portion.
